(19) United States
(12) Patent Application Publication
(10) Pub. No.: US 2012/0163699 A1
(43) Pub. Date: Jun. 28, 2012

(54) MASK DETERMINATION METHOD, EXPOSURE METHOD, AND SEMICONDUCTOR DEVICE MANUFACTURING METHOD

(76) Inventor: Kazuya FUKUHARA, Tokyo (JP)

(21) Appl. No.: 13/231,952

(22) Filed: Sep. 13, 2011

(30) Foreign Application Priority Data
Dec. 28, 2010 (JP) 2010-292657

(51) Int. Cl. G06K 9/00; G03F 7/20

(52) U.S. Cl. 382/144; 430/322

(57) ABSTRACT

According to one embodiment, a mask determination method includes at least one of the in-plane error average value and the distribution of in-plane dispersions in a mask plane are measured with respect to at least one of the dimension and the optical characteristics of a mask pattern formed on a mask. Then, an illumination condition, under which a cost function representing an image performance formed on a substrate approaches a desired value when the exposure light is irradiated onto the mask and an on-substrate pattern is formed, is calculated based on at least one of the measured values. Further, whether the mask is acceptable or defective is determined based on the image performance when the on-substrate pattern is formed under the illumination condition.

### CROSS-REFERENCE TO RELATED APPLICATIONS

This application is based upon and claims the benefit of priority from the prior Japanese Patent Application No. 2010-292657, filed on Dec. 28, 2010; the entire contents of which are incorporated herein by reference.

### FIELD

Embodiments described herein relate generally to a mask determination method, an exposure method, and a semiconductor device manufacturing method.

### BACKGROUND

In the manufacturing process of a semiconductor device, there is a lithography process as a pattern forming process for forming various patterns on a semiconductor substrate (a wafer and the like). In the lithography process, generally, a mask acting as a master for pattern transfer (a photomask for exposure) is used. A pattern on the mask has a dimension obtained by enlarging a pattern to be formed on a semiconductor about 4-5 times and is reduction-transferred onto a wafer using a projection exposure apparatus.

Recently, as the dimension of a circuit pattern of a semiconductor device is miniaturized, a dimensional accuracy required to a mask pattern rapidly is becoming severe. However, in the semiconductor devices, a phenomenon arises in that even if a mask is made to have a pattern as it is designed, a pattern that is the same as the designed pattern cannot be formed on a wafer. The phenomenon includes also a phenomenon, for example, that when an amount of exposure is determined so that a certain pattern is formed in a desired dimension, a different type of a pattern (having a different pitch, a different direction, a different shape, and the like) cannot be formed in a desired dimension. The phenomenon is called a process proximity effect (PPE). PPE is roughly classified into PPE due to a mask process, PPE due to a lithography process, and PPE due to an etching process. Among them, in PPE due to the mask process, the amount of generation of PPE varies depending on some sort of a manufacturing error in a mask manufacturing process. In general, an optical proximity correction (OPC) or a process proximity correction (PPC) for correcting a mask pattern based on the prediction of a PPE generation amount, even in the case, when the PPE generation amount varies, a pattern that is the same as the designed pattern cannot be formed on a wafer.

For example, whether a mask is acceptable or defective is determined after a mask pattern is formed on a mask substrate. At the time, whether the mask is acceptable or defective is determined also as to the error of the PPE generation amount (PPE error) of the mask, and when the PPE error is out of a standard, the mask is determined as a defective product and discarded. As the dimension of a circuit pattern of a semiconductor device is miniaturized, the standards of various determination items including PPE of a mask become severe with a result that the yield of masks is not improved and a mask manufacturing cost becomes high. Therefore, it is desired to improve the yield of masks.

### BRIEF DESCRIPTION OF THE DRAWINGS

FIG. 1 is a view illustrating a mask determination processing procedure according to a first embodiment;

FIG. 2 is a view illustrating a configuration of an exposure condition calculating apparatus;

FIG. 3 is a flow chart illustrating a processing procedure of an exposure condition calculation process;

FIG. 4 is a view illustrating a secondary light source type luminance setting process in which luminance of each pixel is adjusted;

FIG. 5 is a view illustrating a hardware configuration of an exposure condition calculating apparatus; and

FIG. 6A and FIG. 6B are views illustrating a mask providing method according to a second embodiment.

### DETAILED DESCRIPTION

In general, according to one embodiment, a mask determination method is provided. In the mask determination method, includes at least one of the in-plane error average value in a mask plane and the distribution of in-plane dispersions in a mask plane is measured with respect to at least one of the dimension and the optical characteristics of a mask pattern formed on a mask. Then, the illumination condition, under which a cost function representing an image performance formed on a substrate approaches a desired value when the exposure light emitted from an illuminating light source is irradiated onto the mask and an on-substrate pattern is formed on the substrate, is calculated based on at least one of the in-plane error average value and the distribution of in-plane dispersions. Further, whether the mask is acceptable or defective is determined based on whether or not the image performance, when the exposure light is irradiated onto the mask under the illumination condition and an on-substrate pattern is formed on the substrate, is within a predetermined allowable range.

A mask determination method, an exposure method, and a semiconductor device manufacturing method according to the embodiments will be explained below in detail referring to the accompanying drawings. Note that the invention is by no means limited by these embodiments.

### First Embodiment

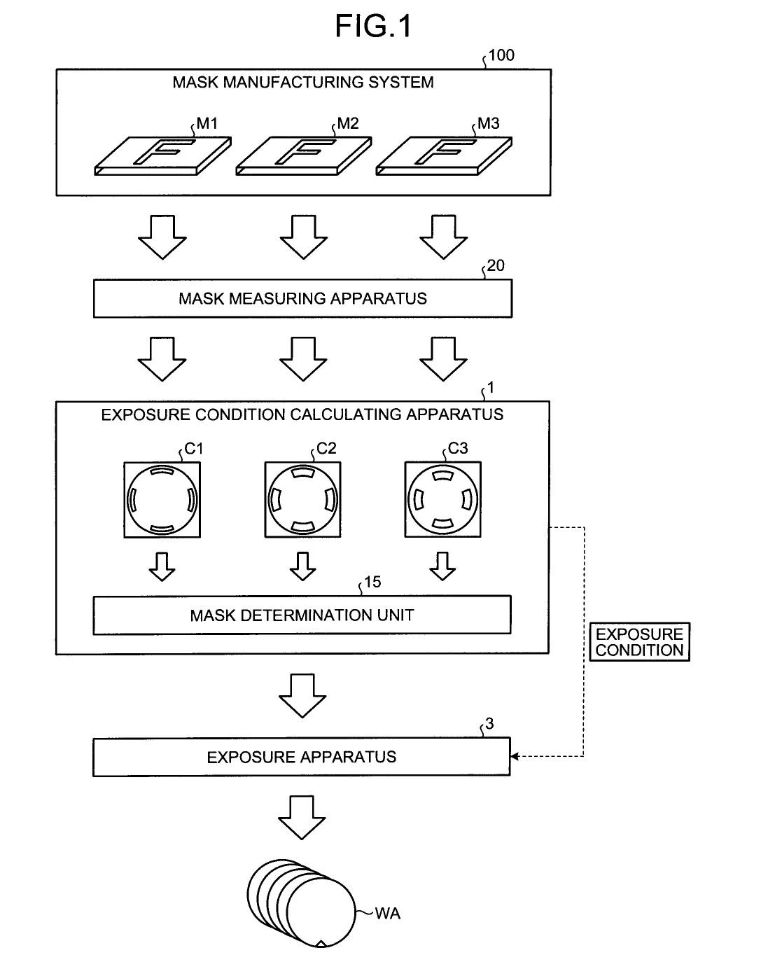

FIG. 1 is a view illustrating a mask determination processing procedure according to a first embodiment. In the embodiment, an exposure condition (an illumination condition, an exposure dosage distribution, and the like) is calculated based on a result of dimensional check of a mask (photomask). Then, whether a mask is acceptable or defective is determined based on whether or not a desired image performance can be obtained when an exposure process is performed onto a substrate such as a wafer and the like using the calculated exposure condition. When it is determined that the mask is an acceptable product, a semiconductor device is manufactured using the calculated exposure condition.

Specifically, a mask used in the exposure process of a photo lithography process is made by a mask making system 100. Here, a case that masks M1-M3 are made is shown. The mask making system 100 comprises, for example, an EB drawing device, a developing device, and the like. A mask pattern corresponding to a designed layout pattern is drawn onto mask blanks (substrates of a lithography master) by the EB drawing device using an electron beam. Further, the mask blanks onto which the mask pattern is drawn using the electron beam is subjected to a developing process by the developing device. With the operation, the masks M1-M3 on which a circuit pattern is formed are made.

The manufactured masks M1-M3 may not be finished to a desired pattern dimension due to a PPE error and the like. For example, even mask patterns having the same dimension, due to an aspect of PPE, may have a different finished dimension depending on their cycle of disposition (pitch). This is called a dimensional density difference. Further, even if PPE has no problem, all types of patterns may have a dimensional error without almost any exception and may not be finished as desired.

The pattern dimensions, the optical characteristics, and the like of the manufactured masks M1-M3 are measured by a mask measuring apparatus 20 as mask measurement information (a check result of mask patterns) which will be described later. For example, as for the mask pattern dimension, at least one of the mask in-plane average value of dimensional errors (error amounts from a desired value) and the distribution of mask in-plane dispersions of a mask pattern dimension is measured. Further, as for the optical characteristics of mask, at least one of the mask in-plane average value of optical characteristics and the distribution of mask in-plane dispersions of optical characteristics may be measured.

That is, the mask measuring apparatus 20 measures at least one of (A)-(D) shown below as the mask measurement information.

(A) The error average value in a mask plane of a mask pattern dimension;

(B) The distribution of mask in-plane dispersions of a mask pattern dimension;

(C) The error average value in a mask plane of mask optical characteristics; and

(D) The distribution of mask in-plane dispersions of mask optical characteristics.

When an attention is paid to one kind of pattern (for example, a pattern having a most strict forming condition), (A) becomes a mask in-plane average value offset amount of the mask pattern dimension. This is, for example, a case that thinning of 2 nm in average occurs to a most miniature pattern in an overall mask plane. Further, when an attention is paid to plural kinds of patterns, (A) is a mask in-plane average offset amount of each pitch of the mask pattern dimension. This is, for example, a case that thinning of 3 nm in average occurs to a pattern having a maximum pitch in an overall mask plane and thinning of 1 nm in average occurs to a pattern having a minimum pitch in an overall mask plane.

When an attention is paid to one kind of a pattern (for example, a pattern having a most strict forming condition), (C) is the mask in-plane average value of mask optical characteristics. Further, when an attention is paid to plural kinds of patterns, (C) is a mask in-plane average offset amount of each pitch of mask optical characteristics.

Further, (B) is the distribution of mask in-plane dispersions of a mask pattern dimension and the like, and (D) is the distribution of mask in-plane dispersions of optical performances of a mask light shield member (for example, a transmittance and a phase difference).

Thereafter, an exposure condition calculating apparatus 1 calculates the exposure condition (the adjustment amount of a set condition of the exposure apparatus) of each of the masks M1-M3 based on the mask measurement information of the respective masks M1-M3. The exposure condition is, for example, an illumination condition (secondary light source shape and the like) in exposure and the in-plane distribution of exposure dosages (an exposure dosage distribution) in a shot.

Shown here is a case that the exposure condition is the illumination condition (the secondary light source shape of a quadruple pole illumination), the illumination condition of the mask M1 is an illumination pupil shape C1, the illumination condition of the mask M2 is an illumination pupil shape C2, and the illumination condition of the mask M3 is an illumination pupil shape C3.

The exposure condition calculating apparatus 1 calculates the illumination condition of each of the masks M1-M3 so that a calculation result (hereinafter, called a cost calculation result) using a cost function as to a resist shape (image performance) approaches a predetermined target value. In other words, the exposure condition calculating apparatus 1 calculates the illumination condition of each of the masks M1-M3 so that, when a pattern (resist pattern) is formed on a wafer using the masks M1-M3, the image performance on the wafer is improved.

The cost function here is a function for evaluating a lithography performance (image performance) and is shown using an optical image feature amount as to the transfer characteristics of a mask pattern onto a wafer. In other words, the cost function is a function representing the performance of an image formed on a wafer. Specifically, the cost function includes information as to an exposure latitude (EL), a depth of focus (DOF), a mask error enhancement factor (MEEF), a dimensional error or a PPE error of resist pattern on wafer, a normalized image log slope (NILS), and a proper exposure dosage, or information as to a combination of them and can be arbitrarily set by a user. For example, the cost function is not limited to a case that it is set as a performance value itself of image and an appropriately modified function such as a square of offset from a target value and the like may be used. The cost function may be, for example, a function representing the difference between the desired dimension and the predicted dimension of a resist pattern or may be a function representing the difference between the desired value and the predicted value of the depth of focus.

The cost function is set such that a low cost calculation result (for example, 0) is calculated to the illumination condition by which an image performance near to a desired image performance can be obtained and a high cost calculation result is calculated to an illumination condition by which only an image performance away from the desired image performance can be obtained. The exposure condition calculating apparatus 1 calculates the illumination condition for eliminating at least one of (A)-(D) described above using the cost function. Further, the exposure condition calculating apparatus 1 may calculate the exposure dosage distribution condition for eliminating (B) and (D) described above.

Then, a mask determination unit 15 of the exposure condition calculating apparatus 1 determines that a mask is accepted when the image performance on a wafer is within an allowable range at the time the wafer is exposed under the calculated illumination condition (determines that the mask is an acceptable product), whereas when the image performance on the wafer is out of the allowable range, the mask determination unit 15 determines that the mask is defective.

Further, when an exposure dosage distribution condition within a predetermined range can be calculated, the mask determination unit 15 of the exposure condition calculating apparatus 1 may determine that the mask is accepted (may determine that the mask is the acceptable product), whereas when the exposure dosage distribution condition cannot be calculated, the mask determination unit 15 may determine that the mask is defective.

Thereafter, an exposure apparatus 3 performs an exposure process onto a wafer WA using the mask which is determined acceptable. At the time, the exposure apparatus 3 performs the exposure process to each of the masks M1-M3 using the exposure condition of each of the masks M1-M3 calculated by the exposure condition calculating apparatus 1. When, for example, it is determined that the mask M1 is accepted, the exposure apparatus 3 performs the exposure process to the wafer WA using the exposure condition (the illumination pupil shape C1 and the like) of the mask M1 calculated by the exposure condition calculating apparatus 1. With the operation, a resist pattern having a desired image performance (a desired pattern dimension) is formed on the wafer. Hereinafter, any of the masks M1-M3 may be called a mask Mx for the purpose of convenience of explanation.

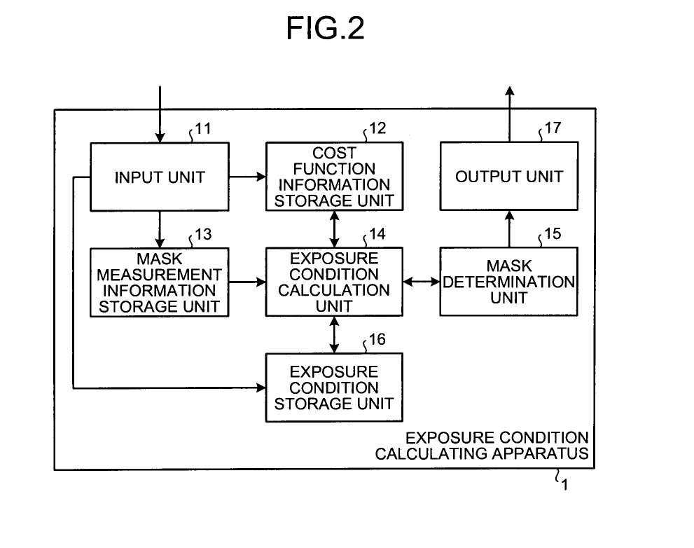

Next, a configuration of the exposure condition calculating apparatus 1 will be explained. FIG. 2 is a view illustrating a configuration of the exposure condition calculating apparatus. The exposure condition calculating apparatus 1 includes an input unit 11, a cost function information storage unit 12, a mask measurement information storage unit 13, an exposure condition calculation unit 14, a mask determination unit 15, an exposure condition storage unit 16, and an output portion 17.

The input unit 11 inputs information (cost function information) as to the cost function and sends the information to the cost function information storage unit 12. Further, the input unit 11 inputs mask measurement information (dimension of mask pattern and optical characteristics of mask) and sends the information to the mask measurement information storage unit 13. The cost function information is information including the cost function, a target value of the value calculated by the cost function (hereinafter, called a cost target value) and the like. Further, the input unit 11 inputs the initial value of the exposure condition and sends the initial value to the exposure condition storage unit 16.

The cost function information storage unit 12 is a memory and the like for storing the cost function information and the current value of the cost function calculated by the exposure condition calculation unit 14 (a latest cost calculation result) (hereinafter, called a cost current value). The mask measurement information storage unit 13 is a memory and the like for storing the mask measurement information. The exposure condition storage unit 16 is a memory and the like for storing the initial value of the exposure condition and the latest exposure condition which is calculated by the exposure condition calculation unit 14.

The exposure condition calculation unit 14 calculates the exposure condition of each of the masks M1-M3 using the cost function information and the cost current value in the cost function information storage unit 12, the mask measurement information in the mask measurement information storage unit 13, and the exposure condition (the latest exposure condition or the initial value of the exposure condition) in the exposure condition storage unit 16. The exposure condition calculation unit 14 calculates the exposure condition which causes the cost calculation result to approach the cost target value more closely than the cost current value to each of the masks M1-M3. When, for example, the cost target value is X, the exposure condition calculation unit 14 calculates the exposure condition which causes the cost calculation result to approach X more closely than the current value.

The exposure condition calculation unit 14 causes the cost function information storage unit 12 to store the cost calculation result corresponding to the exposure condition as a new cost current value. The exposure condition calculation unit 14 causes the exposure condition storage unit 16 to store the calculated exposure condition of the mask Mx as the latest exposure condition. Further, the exposure condition calculation unit 14 sends the calculated exposure condition of each of the masks M1-M3 and the mask measurement information of each of the masks M1-M3 to the mask determination unit 15.

The exposure condition calculation unit 14 calculates the exposure condition which causes the cost calculation result to approach the cost target value or to become the same as the cost target value by repeating the calculation process of the exposure condition. When a mask is not determined acceptable even if the exposure condition calculation unit 14 repeats the calculation process of the exposure condition a predetermined number of times, the exposure condition calculation unit 14 finishes the calculation process of the exposure condition in response to an instruction from the mask determination unit 15.

As a method for canceling the influence of (A) and (C) described above (a canceling method for the error average value), there is a method of adjusting the illumination condition of the exposure apparatus 3 as the exposure condition. In the method, the exposure condition calculation unit 14 calculates the adjustment amount of the secondary light source shape of the exposure apparatus 3. Originally, an arbitrary mask pattern is designed such that when the mask pattern is exposed by the exposure apparatus 3 under a predetermined illumination condition (i.e. standard condition), a desired on-wafer pattern can be formed on a wafer. The exposure condition calculation unit 14 adjusts the standard condition in response to, for example, the characteristics of the mask. A secondary light source shape adjustment method has two kinds of methods.

A first secondary light source shape adjustment method is a method of changing a shape parameter such as a a value, an open angle, and the like. A second secondary light source shape adjustment method is a method of prescribing the distribution of secondary light source luminance by the aggregation of pixels and adjusting the luminance of the respective pixels. It can be prevented that the influence of the mask in-plane error average value of a mask pattern appears as the dimensional change of a resist pattern by changing the setting of the secondary light source shape of the exposure apparatus 3 using at least one of the methods. The methods are effective for, for example, the correction of the in-plane average error of PPE of a mask.

Further, as a method for canceling the influence of (B) and (D) described above (a canceling method of the distribution of in-plane dispersions), there are two methods shown below. A first cancel method of the distribution of in-plane dispersions is a method of adjusting the illumination condition of the exposure apparatus 3 described above. The method increases a process window of a pattern having a large dimensional dispersion by adjusting the illumination condition. As for the process window, there are the exposure latitude, the depth of focus, the mask error enhancement factor (sensitivity to dispersion of mask dimensions), and the like.

Further, a second canceling method of the distribution of in-plane dispersions is a method of controlling the distribution of exposure dosages in the shot. In the method, the exposure dosage in a mask plane is changed in response to the dimensional error of a mask, thereby suppressing the dispersion of the dimensions of a resist pattern on a wafer. In the method, the exposure condition calculation unit 14 calculates the distribution of the exposure dosage in the mask.

Here, an exposure dosage distribution control method in a shot will be explained. It is assumed, for example, that the line widths of a pattern formed on a mask have a distribution only in a scan direction and have a constant width in a direction vertical to the scan direction. Further, it is assumed that when an exposure is performed, light has uniform illuminance on a non-irradiated surface. In the case, there is a mask pattern in which the line width of a resist pattern becomes thicker than a desired value when it is exposed in a standard exposure dosage. In the case, to form a resist pattern having a desired line width, the exposure dosage is made smaller than the standard exposure dosage.

Originally, the exposure apparatus 3 is adjusted so that the exposure dosage may become uniform in the shot (a region in which the overall pattern of a mask is exposed). Therefore, in the exposure dosage distribution control method in the shot, the uniformity of the exposure dosage is deteriorated in response to the state of a mask (mask measurement information), thereby an adjustment is performed so that a resist pattern dimension may become uniform. With the operation, a pattern having a uniform line width can be transferred onto a resist regardless of the distribution of the line widths of a mask pattern. Note that the exposure dosage is controlled by, for example, changing the scan speed (moving speed) of a reticle stage and a wafer stage.

To cancel the influence of at least one of (A)-(D) described above, the exposure condition calculation unit 14 calculates the proper exposure condition (a desirable adjustment amount of the exposure apparatus) to each mask Mx using at least one of the error average value canceling method and the distribution of in-plane dispersions canceling method.

Specifically, when the exposure light emitted from the illuminating light source is irradiated onto a mask and an on-wafer pattern is formed on a wafer, the exposure condition calculation unit 14 calculates the illumination condition for causing the cost function to approach the desired value based on at least one of (A)-(D) described above. The exposure condition calculation unit 14 may calculate the distribution of exposure dosages in which the dimensional dispersion of on-wafer patterns formed, when the exposure light emitted from the illuminating light source is irradiated onto a mask, is made to a predetermined value or less based on at least one of (B), (D) described above. Further, the exposure condition calculation unit 14 may calculate both the illumination condition under which the cost function approaches the desired value and the distribution of the exposure dosages in which the dimensional dispersion of the on-wafer patterns is made to the predetermined value or less. In the embodiment, the case will be explained that the exposure condition calculation unit 14 calculates both the illumination condition under which the cost function approaches the desired value and the distribution of the exposure dosages in which the dimensional dispersion of the on-wafer patterns are made to the predetermined value or less.

The mask determination unit 15 calculates the image performance (the resist pattern dimension) using the illumination condition sent from the exposure condition calculation unit 14, and the mask measurement information. In other words, the mask determination unit 15 predicts the dimension of a resist pattern by, for example, an imaging calculation process and a lithography simulation by a lithography simulator and the like. The lithography-simulator used here is a simulator for performing a calculation including the effect of, for example, exposure, PEB, development, and the like.

The mask determination unit 15 determines whether or not the mask Mx is an acceptable product based on whether or not a calculated image performance is within an allowable range. When the calculated image performance is within the allowable range, the mask determination unit 15 determines that the mask Mx is the acceptable product. In other words, when the predicted resist pattern fulfils a management standard, it is determined that the mask is the acceptable product and shipped. At the time, information as to latest calculated exposure condition (the adjustment amount of the exposure apparatus 3) may be provided to a mask user together. In contrast, when the predicted resist pattern does not fulfill the management standard, it is determined that the mask is a defective product and discarded.

When the mask Mx is the acceptable product (accepted) as a result of determination, the mask determination unit 15 sends the result of determination of the mask Mx and the exposure condition of the mask Mx to the output unit 17. When the mask Mx is a defective product as the result of determination, the mask determination unit 15 sends the result of determination of the mask Mx to the output unit 17. Further, when the mask Mx is the defective product as the result of determination, the mask determination unit 15 instructs the exposure condition calculation unit 14 to calculate the exposure condition again. Even if the exposure condition calculation unit 14 repeats the calculation process of the exposure condition a predetermined number of times, the mask determination is not accepted, the mask determination unit 15 instructs the exposure condition calculation unit 14 to finish the calculation process of the exposure condition. The output unit 17 outputs the result of determination of the mask Mx and the exposure condition of the mask Mx to an external device and the like.

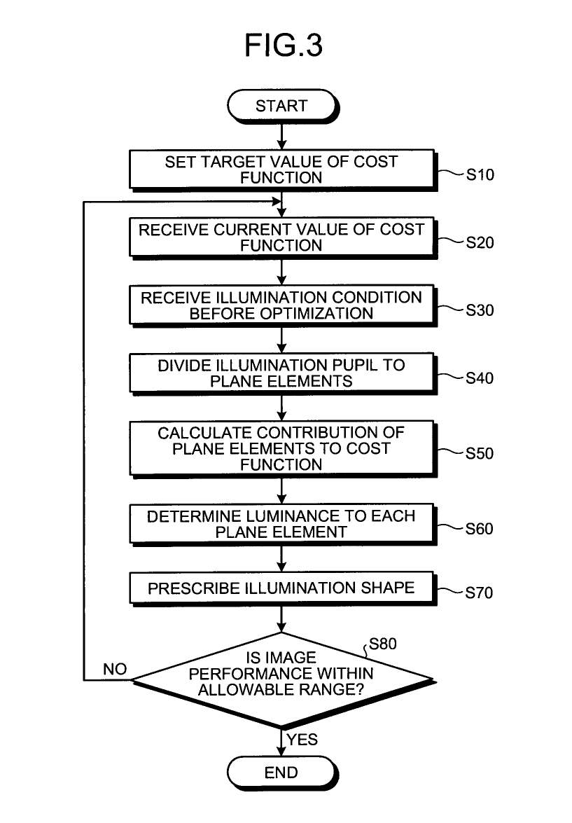

Next, a calculation processing procedure of the exposure condition will be explained. FIG. 3 is a flowchart illustrating the processing procedure of an exposure condition calculation process. Note that a case that the illumination condition is calculated as the exposure condition will be explained here. Further, a case that the secondary light source shape of the quadruple pole illumination is calculated to each plane elements of an illumination pupil as the illumination condition, will be explained here.

The input unit 11 of the exposure condition calculating apparatus 1 is previously input with the cost function information composed of the cost function and the cost target value, the mask measurement information of each mask Mx, and the initial value of the exposure condition.

The input unit 11 sends the cost function information to the cost function information storage unit 12 and sends the mask measurement information to the mask measurement information storage unit 13. Further, the input unit 11 sends the initial value of the exposure condition to the exposure condition storage unit 16. With the operation, the cost function information storage unit 12 is set with the cost function and a cost target value as a target value of the cost function (step S10). Further, the mask measurement information storage unit 13 is set with the mask measurement information and the exposure condition storage unit 16 is set with the initial value of the exposure condition.

The exposure condition calculation unit 14 receives the cost function and the cost current value as a current value of the cost function from the cost function information storage unit 12 (step S20). Since the cost function information storage unit 12 does not store the cost current value therein here, the exposure condition calculation unit 14 receives the cost function from the cost function information storage unit 12.

Further, the exposure condition calculation unit 14 receives the illumination condition before it is optimized as the initial value of the exposure condition from the exposure condition storage unit 16 (step S30). The exposure condition calculation unit 14 calculates the exposure condition of the mask Mx using the cost function information, the mask measurement information, and the initial value of the exposure condition. The exposure condition calculation unit 14 prescribes the distribution of the secondary light source luminance by the aggregation of pixels and calculates the secondary light source shape of illumination obtained by adjusting the luminance of the respective pixels as the exposure condition.

Specifically, the exposure condition calculation unit 14 reads the initial condition (the illumination condition before optimization) of the illumination pupil as the initial value of the exposure condition from the exposure condition storage unit 16. The illumination condition before it is optimized may be, for example, a region (light source region) in which the secondary light source shape is set and may be, for example, the secondary light source shape of the quadruple pole illumination to which the predetermined o value, the predetermined open angle, and the like are set. The exposure condition calculation unit 14 divides the read initial condition of the illumination pupil to plane elements by an N-th pitch (N is a natural number) (here N=1) (step S40).

Then, the exposure condition calculation unit 14 calculates the contribution of the respective divided plane elements to the cost function (step S50). At the time, the exposure condition calculation unit 14 determines the luminance to each plane element so that the cost function approaches the target value (step S60). In other words, the exposure condition calculation unit 14 calculates the influence of the luminance of plane elements on the cost calculation result, and determines the luminance of the plane elements for causing the calculation result to approach the target value. The exposure condition calculation unit 14 repeats the process to the respective plane elements, thereby calculating the luminance of all the plane elements in the illumination pupil setting plane. With the operation, the exposure condition calculation unit 14 prescribes a first illumination shape as the exposure condition (step S70).

The exposure condition calculation unit 14 causes the cost function information storage unit 12 to store the cost calculation result corresponding to the exposure condition as a new cost current value. Further, the exposure condition calculation unit 14 causes the exposure condition storage unit 16 to store the calculated exposure condition of the mask Mx as a latest exposure condition. Further, the exposure condition calculation unit 14 sends the calculated exposure condition of the mask Mx and the mask measurement information of the mask Mx to the mask determination unit 15.

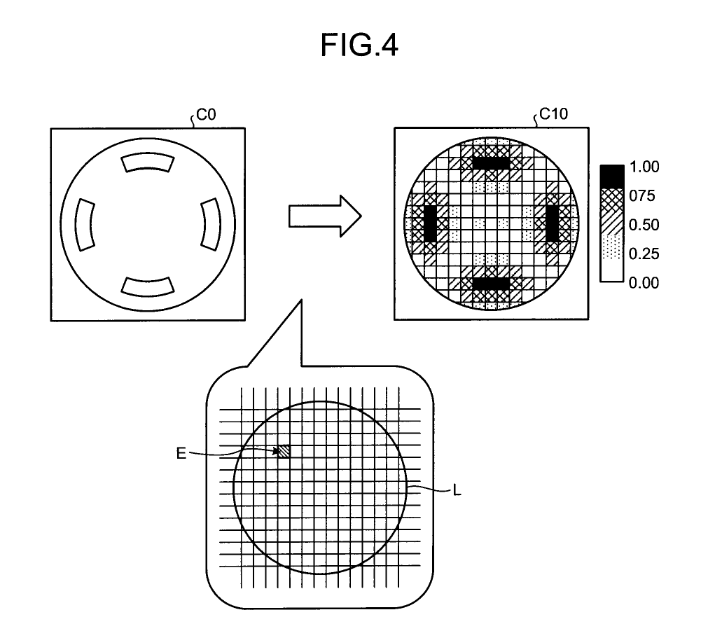

FIG. 4 is a view illustrating a secondary light source type luminance setting process in which luminance of each pixel is adjusted. The inside of an illumination pupil setting plane L is divided to the respective plane elements E corresponding to the illumination pupil shape C0 of an initial condition. Then, luminance is set to each of the plane elements E. For example, the respective plane elements are set to any of luminance 0.00-0.25, luminance 0.25-0.50, luminance 0.50-0.75, and luminance 0.75-1.00. As a result, the illumination pupil shape C10 having an optimum condition can be obtained.

The mask determination unit 15 calculates the image performance (the resist pattern dimension) using the illumination shape prescribed by the exposure condition calculation unit 14 and the mask measurement information. The mask determination unit 15 determines whether or not the mask Mx is an acceptable product based on whether or not the calculated image performance is within the allowable range (step S80).

When the calculated image performance is out of the allowable range (step S80, No), the mask determination unit 15 determines that the mask Mx is a defective product. In the case, the exposure condition calculating apparatus 1 returns to a process at step S20 and repeats the processes of steps S20-S80.

Specifically, the mask determination unit 15 instructs the exposure condition calculation unit 14 to calculate the exposure condition again. The exposure condition calculation unit 14 receives the cost function and the cost current value from the cost function information storage unit 12 (step S20).

Further, the exposure condition calculation unit 14 receives the latest exposure condition from the exposure condition storage unit 16 (step S30). The exposure condition calculation unit 14 newly calculates the exposure condition of the mask Mx using the cost function information, the mask measurement information, the latest exposure condition, and the cost current value. At the time, the exposure condition calculation unit 14 divides the illumination pupil corresponding to the latest exposure condition into plane elements by an (N+1)-th division pitch (step S40).

Then, the exposure condition calculation unit 14 calculates the contribution of the respective divided plane elements to the cost function (step S50). At the time, the exposure condition calculation unit 14 determines the luminance of each plane element so that the cost function approaches the target value (step S60). As described above, the illumination shape is calculated by properly designing the luminance distribution of the illumination pupil having the luminance distribution.

In other words, the following processes of (S1)-(S6) are performed.

(S1) A luminance distribution showing an N-th illumination shape in an illumination pupil is prepared. The N-th illumination shape is an illumination shape in which the illumination condition is repeated (N-1) times.

(S2) The N-th division pitch for dividing the illumination pupil to the plane elements is prescribed.

(S3) The illumination pupil is divided to the plane elements by the division pitch.

(S4) The luminance adjustment amounts of the respective plane elements are determined to the N-th luminance distribution and an (N+1)-th luminance distribution is calculated.

(S5) A (N+1)-th division pitch different from the N-th division pitch is prescribed.

(S6) The processes of (S3) and (S4) described above are performed to the (N+1)-th luminance distribution.

The mask determination unit 15 calculates the image performance using the illumination shape prescribed by the exposure condition calculation unit 14 and the mask measurement information. The mask determination unit 15 determines whether or not the mask Mx is the acceptable product based on whether or not the calculated image performance is within the allowable range (step S80).

When the calculated image performance is out of the allowable range (step S80, No), the mask determination unit 15 determines that the mask Mx is the defective product. The exposure condition calculating apparatus 1 repeats the processes of step S20-S80 until the calculated image performance is within the allowable range. When the calculated image performance is within the allowable range (step S80, Yes), the mask determination unit 15 determines that the mask Mx is an acceptable product. Thereafter, the exposure condition of the mask Mx which is determined as an acceptable product is output from the output unit 17.

The exposure apparatus 3 irradiates the light emitted from the illumination pupil C10 having the luminance distribution prescribed as the exposure condition of the mask Mx which is determined as the acceptable product onto the mask Mx and exposes the image of the mask Mx onto a wafer. In other words, when a semiconductor device is manufactured using the mask Mx which is determined as the acceptable product, exposure is performed by setting the calculated adjustment amount of the exposure apparatus 3 to the exposure apparatus 3. As a result, the dimensional accuracy of a resist pattern can be enhanced.

As described above, the setting of the exposure apparatus 3 is adjusted so that the influence of the dimensional error of a mask is reduced. As a result, a mask which is conventionally determined as a defective product can be more often used as an acceptable product.

Note that a mask pattern, which is used as a determination target in the determination of mask in the embodiment, may be, for example, a mask pattern to which a sophisticated dimensional control is required. For example, the mask pattern as the determination target of the determination of mask includes a mask pattern having a smallest process window in a mask.

The manufacturing of a mask by the mask making system 100, the measurement of mask measurement information by the mask measuring apparatus 20, the calculation of an exposure condition and the determination of a mask by the exposure condition calculating apparatus 1, and the exposure process by the exposure apparatus 3 are performed to, for example, each layer of a wafer process.

Then, a semiconductor device (a semiconductor integrated circuit) is manufactured using a mask whose exposure condition is calculated and which is determined acceptable. Specifically, a wafer coated with a resist is exposed by being applied with the mask determined acceptable and the exposure condition and thereafter a resist pattern is formed on the wafer by developing the wafer. Then, the lower layer side of the resist pattern is etched using the resist pattern as a mask. With the operation, an actual pattern corresponding to the resist pattern is formed on the wafer. When the semiconductor device is manufactured, the exposure process using the mask determination described above and the exposure condition calculated as described above, the developing process, the etching process, and the like are repeated to each layer.

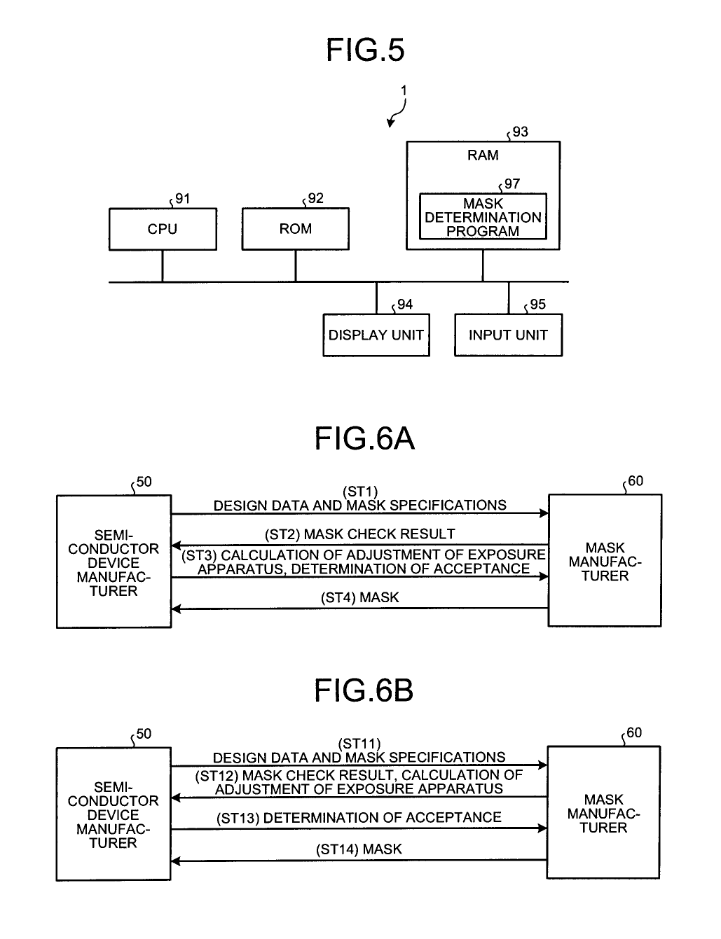

Next, a hardware configuration of the exposure condition calculating apparatus 1 will be explained. FIG. 5 is a view illustrating the hardware configuration of the exposure condition calculating apparatus 1. The exposure condition calculating apparatus 1 includes a CPU (central processing unit) 91, a ROM (read only memory) 92, a RAM (random access memory) 93, a display unit 94, and an input unit 95. In the exposure condition calculating apparatus 1, the CPU 91, the ROM 92, the RAM 93, the display unit 94, and the input unit 95 are connected to each other via a bus line.

The CPU 91 determines a pattern using a mask determination program 97 which is a computer program. The display unit 94 is a display device such as a liquid crystal monitor and the like and displays the mask measurement information, the cost function information, the exposure condition, the result of determination of mask, and the like based on the instruction from the CPU 91. The input unit 95 is composed of a mouse and a key board and inputs instruction information (a parameter and the like necessary to determine a mask) externally input from the user. The instruction information input to the input unit 95 is sent to the CPU 91.

The mask determination program 97 is stored in the ROM 92 and loaded in the RAM 93 via the bus line. FIG. 5 illustrates a state that the mask determination program 97 is loaded in the RAM 93.

The CPU 91 executes the mask determination program 97 loaded in the RAM 93. Specifically, in the exposure condition calculating apparatus 1, the CPU 91 reads the mask determination program 97 from the ROM 92 in response to the instruction input from the input unit 95 by the user, develops the mask determination program 97 in a program storage region in the RAM 93, and performs various processes. The CPU 91 causes a data storage region formed in the RAM 93 to temporarily store various data generated when the various processes are performed.

The mask determination program 97 executed by the exposure condition calculating apparatus 1 is configured as a module including the exposure condition calculation unit 14 and the mask determination unit 15 which are loaded on a main storage device and generated on the main storage device.

Note that the mask determination program 97 may be a program for executing the function of any one of the exposure condition calculation unit 14 and the mask determination unit 15 or may be a program for executing the functions of both the exposure condition calculation unit 14 and the mask determination unit 15.

As described above, according to the first embodiment, when the exposure condition according to the mask Mx is calculated and a wafer is exposed under the calculated exposure condition, since a mask whose image performance is within the allowable range is determined as an acceptable product, the mask yield is improved, thereby a mask manufacturing cost is reduced.

Note that, in the embodiment, although the method of canceling the influence of (A) and (C) described above (the method of canceling the error average value) is explained using the method of adjusting the illumination condition (the secondary light source shape) of the exposure apparatus 3 as the exposure condition, the adjustment can be also performed using a means other than the illumination condition (the secondary light source shape). That is, any arbitrary means capable of changing the imaging performance of the exposure apparatus such as the adjustment of, for example, the numerical number (NA) of a projection lens, the adjustment of aberration of the projector lens, and the like can be used.

### Second Embodiment

Next, a second embodiment of the invention will be explained using FIG. 6A and FIG. 6B. In the second embodiment, a business model (mask sales business) using the mask determination method explained in the first embodiment will be explained.

FIG. 6A and FIG. 6B are views illustrating a mask providing method according to the second embodiment. In the method illustrated in FIG. 6A, a mask is provided to a semiconductor device manufacturer 50 in the procedures of (ST1)-(ST4).

(ST1) The semiconductor device manufacturer 50 submits design data and mask specifications to a mask manufacturer 60.

(ST2) The mask manufacturer 60 manufactures a mask as well as checks the mask based on the design data and mask specifications.

(ST3) The semiconductor device manufacturer 50 calculates the exposure condition (the setting condition) to the exposure apparatus 3 suitable for the manufactured mask based on a mask check result (mask measurement information). The semiconductor device manufacturer 50 determines the mask performance under the calculated exposure condition.

(ST4) The semiconductor device manufacturer 50 receives the mask which is determined acceptable by the determination of the mask performance from the mask manufacturer 60.

Further, in the method illustrated in FIG. 6B, a mask is provided to the semiconductor device manufacturer 50 in the procedures of (ST11)-(ST14).

(ST11) A semiconductor device manufacturer 50 submits design data and mask specifications to a mask manufacturer 60.

(ST12) The mask manufacturer 60 manufactures a mask as well as checks the mask based on the design data and mask specifications. Further, the mask manufacturer 60 calculates the exposure condition to an exposure apparatus 3 suitable for the mask based on a mask check result.

(ST13) The semiconductor device manufacturer 50 determines the mask performance under the calculated exposure condition.

(ST14) The semiconductor device manufacturer 50 receives the mask which is determined acceptable by the determination of the mask performance from the mask manufacturer 60.

In the method illustrated in FIG. 6B, the semiconductor device manufacturer 50 submits information (a standard illumination condition, a simulation method, a process parameter, and the like) which is necessary to calculate, for example, the exposure condition of the exposure apparatus 3 to the mask manufacturer 60. Note that a mask price may be changed according to the situation such as whether a mask is determined as an acceptable product without changing the exposure condition of the exposure apparatus 3 or by changing the exposure condition of the exposure apparatus 3.

As described above, according to the first and second embodiments, the mask yield is improved, thereby reducing a mask manufacturing cost.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A mask determination method comprising:
measuring at least one of the in-plane error average value in a mask plane and the distribution of in-plane dispersions in a mask plane with respect to at least one of the dimension and the optical characteristics of a mask pattern formed on a mask;
calculating the illumination condition under which a cost function representing an image performance formed on a substrate approaches a desired value when exposure light emitted from an illuminating light source is irradiated onto the mask and an on-substrate pattern is formed on the substrate based on at least one of the in-plane error average value and the distribution of in-plane dispersions; and
determining whether the mask is acceptable or defective based on whether or not the image performance, when exposure light is irradiated onto the mask under the illumination condition and an on-substrate pattern is formed on the substrate, is within a predetermined allowable range.

2. The mask determination method according to claim 1, wherein the image performance is a function representing the performance of an image formed a substrate and is shown using at least one of an exposure latitude, a depth of focus, a mask error enhancement factor, a dimensional error of the on-substrate pattern, a PPE error of the on-substrate pattern, a normalized image log slope, and a proper exposure dosage.

3. The mask determination method according to claim 1, wherein the illumination condition is the secondary light source shape of the illuminating light source.

4. The mask determination method according to claim 1, wherein the optical characteristics are at least one of the transmittance or the phase difference of a light shield member formed to the mask pattern.

5. The mask determination method according to claim 1, wherein a process window when the exposure light emitted from the illuminating light source is irradiated onto the mask and an on-substrate pattern is formed on the substrate includes at least one of an exposure latitude, a depth of focus, and sensitivity to a mask dimensional dispersion.

6. The mask determination method according to claim 1 comprising:
calculating an exposure dosage distribution in which the dimensional dispersion of an on-substrate pattern formed when the exposure light emitted from the illuminating light source is irradiated onto the mask is within a predetermined amount or less based on the distribution of an in-plane dispersion; and
determining whether the mask is acceptable or defective based on whether or not the exposure dosage distribution in which the dimensional dispersion is within the predetermined value or less can be calculated or the image performance when exposure light is irradiated onto the mask under the illumination condition and an on-substrate pattern is formed on the substrate is within a predetermined allowable range.

7. An exposing method comprising:
measuring at least one of the in-plane error average value in a mask plane and the distribution of in-plane dispersions in a mask plane with respect to at least one of the dimension and the optical characteristics of a mask pattern formed on a mask;
calculating the illumination condition under which a cost function representing an image performance formed on a substrate approaches a desired value when exposure light emitted from an illuminating light source is irradiated onto the mask and an on-substrate pattern is formed on the substrate based on at least one of the in-plane error average value and the distribution of in-plane dispersions; and
performing exposure onto a substrate using the mask under the illumination condition.

8. The exposing method according to claim 7, comprising:
determining whether the mask is acceptable or defective based on whether or not the image performance when exposure light is irradiated onto the mask under the illumination condition and an on-substrate pattern is formed on the substrate is within a predetermined allowable range; and
performing exposure onto a substrate using the mask determined as an acceptable mask.

9. The exposing method according to claim 7, wherein the image performance is a function representing the performance of an image formed a substrate and is shown using at least one of an exposure latitude, a depth of focus, a mask error enhancement factor, a dimensional error of the on-substrate pattern, a PPE error of the on-substrate pattern, a normalized image log slope, and a proper exposure dosage.

10. The exposing method according to claim 7, wherein the illumination condition is the secondary light source shape of the illuminating light source.

11. The exposing method according to claim 7, wherein the optical characteristics are at least one of the transmittance or the phase difference of a light shield member formed to the mask pattern.

12. The exposing method according to claim 7, wherein a process window when the exposure light emitted from the illuminating light source is irradiated onto the mask and an on-substrate pattern is formed on the substrate includes at least one of an exposure latitude, a depth of focus, and sensitivity to a mask dimensional dispersion.

13. The exposing method according to claim 8 comprising:
calculating an exposure dosage distribution in which the dimensional dispersion of an on-substrate pattern formed when the exposure light emitted from the illuminating light source is irradiated onto the mask is within a predetermined amount or less based on the distribution of an in-plane dispersion; and
determining whether the mask is acceptable or defective based on whether or not the exposure dosage distribution in which the dimensional dispersion is within the predetermined value or less can be calculated and the image performance when exposure light is irradiated onto the mask under the illumination condition and an on-substrate pattern is formed on the substrate is within a predetermined allowable range.

14. A semiconductor device manufacturing method comprising:
measuring at least one of the in-plane error average value in a mask plane and the distribution of in-plane dispersions in a mask plane with respect to at least one of the dimension and the optical characteristics of a mask pattern formed on a mask;
calculating the illumination condition under which a cost function representing an image performance formed on a substrate approaches a desired value when exposure light emitted from an illuminating light source is irradiated onto the mask and an on-substrate pattern is formed on the substrate based on at least one of the in-plane error average value and the distribution of in-plane dispersions; and
performing exposure onto a substrate using the mask under the illumination condition; and
forming an on-substrate pattern on the exposed substrate.

15. The semiconductor device manufacturing method according to claim 14, comprising:
determining whether the mask is acceptable or defective based on whether or not the image performance when exposure light is irradiated onto the mask under the illumination condition and an on-substrate pattern is formed on the substrate is within a predetermined allowable range;
performing exposure onto a substrate using the mask determined as an acceptable mask; and
forming an on-substrate pattern on the exposed substrate.

16. The semiconductor device manufacturing method according to claim 14, wherein the image performance is a function representing the performance of an image formed a substrate and is shown using at least one of an exposure latitude, a depth of focus, a mask error enhancement factor, a dimensional error of the on-substrate pattern, a PPE error of the on-substrate pattern, a normalized image log slope, and a proper exposure dosage.

17. The semiconductor device manufacturing method according to claim 14, wherein the illumination condition is the secondary light source shape of the illuminating light source.

18. The semiconductor device manufacturing method according to claim 14, wherein the optical characteristics are at least one of the transmittance or the phase difference of a light shield member formed to the mask pattern.

19. The semiconductor device manufacturing method according to claim 14, wherein a process window when the exposure light emitted from the illuminating light source is irradiated onto the mask and an on-substrate pattern is formed on the substrate includes at least one of an exposure latitude, a depth of focus, and sensitivity to a mask dimensional dispersion.

20. The semiconductor device manufacturing method according to claim 15 comprising:
calculating an exposure dosage distribution in which the dimensional dispersion of an on-substrate pattern formed when the exposure light emitted from the illuminating light source is irradiated onto the mask is within a predetermined amount or less based on the distribution of an in-plane dispersion; and
determining whether the mask is acceptable or defective based on whether or not the exposure dosage distribution in which the dimensional dispersion is within the predetermined value or less can be calculated and the image performance, when exposure light is irradiated onto the mask under the illumination condition and the on-substrate pattern is formed on the substrate, is within a predetermined allowable range.
